(19) United States
(12) Patent Application Publication
(10) Pub. No.: US 2024/0266251 A1
(43) Pub. Date: Aug. 8, 2024

(54) DIRECT COOLING TYPE SEMICONDUCTOR PACKAGE UNIT AND MANUFACTURING METHOD THEREOF

(71) Applicant: Republic Of Korea (Defense Acquisition Program Administration), Gwacheon-si (KR)

(72) Inventors: Jun Rae PARK, Ansan-si (KR); Min Soo KANG, Seoul (KR); Hae Cheon KIM, Daejeon (KR); Hyoung Soon LEE, Seoul (KR); Sung Jae CHANG, Daejeon (KR); Hyun Wook JUNG, Daejeon (KR); Il Gyu CHOI, Jeonju-si (KR); Seong Il KIM, Daejeon (KR); Sang Heung LEE, Daejeon (KR); Ho Kyun AHN, Daejeon (KR); Jong Won LIM, Daejeon (KR)

(21) Appl. No.: 18/432,049

(22) Filed: Feb. 4, 2024

(30) Foreign Application Priority Data
Feb. 3, 2023 (KR) 10-2023-0014773

(51) Int. Cl. H01L 23/46; H01L 21/48

(52) U.S. Cl. CPC H01L 23/46; H01L 21/4882

(57) ABSTRACT

A direct cooling type semiconductor package unit includes a substrate made of a material capable of manufacturing a semiconductor device, and having a material layer for forming the semiconductor device stacked on one side of the substrate, and a flow channel through which a cooling fluid flows formed on the other side of the substrate to enable direct cooling of the semiconductor device using the cooling fluid; a packaging block disposed at a position spaced apart from the substrate for packaging the semiconductor device, and having an electrode electrically connected to the semiconductor device through wiring and placed thereon to be insulated; a heat sink unit disposed on a lower side of the packaging block and having a fluid movement region formed at a position corresponding to a flow channel of the substrate; and a thin film type structure disposed between the substrate and the heat sink unit for coupling between the substrate and the heat sink unit and being moldable to have pattern structures of various shapes through a dry film resist (DFR) lithography process.

In addition, the present disclosure is the future challenge defense technology research and development (Project No. UI220007TD, No. 915028201) conducted with the support of the Agency for Defense Development of the Republic of Korea with funding from the Government (Defense Acquisition Program Administration) for a period of Jan. 3, 2022 to Nov. 30, 2026 (59 months).

### Project Details

[Ministry Name] Defense Acquisition Program Administration
[Research Management Specialized Institution] Agency for Defense Development
[Research Project Name] Future challenge defense technology research and development project
[Research period] Jan. 3, 2022 to Nov. 30, 2026 (59 months)
[Project name/Project number] Research and development of high-power GaN device with self-heat dissipation function (No. 915028201)

### CROSS-REFERENCE TO RELATED APPLICATIONS

This application claims the priority of Korean Patent Application No. 10-2023-0014773 filed on Feb. 3, 2023, in the Korean Intellectual Property Office, the entire contents of which is incorporated herein by reference.

### TECHNICAL FIELD

The present disclosure relates to a direct cooling type semiconductor package unit and a manufacturing method thereof, and more particularly, to a direct cooling type semiconductor package unit with improved structure and process, in which a substrate and a heat sink unit are in close contact with each other by using a thin film type structure that is moldable to have pattern structures of various shapes through a lithography process so that a cooling fluid may flow into a flow channel side of the substrate without loss, and a manufacturing method thereof.

### BACKGROUND ART

Recently, with the high performance and miniaturization of semiconductor devices, the amount of heat generated continues to increase, which causes problems in which the performance, efficiency, and reliability of semiconductor devices degrade. To solve the problems, research has been actively conducted on embedded cooling in which a micro channel is formed on the rear of a semiconductor and connected to an external manifold to allow a coolant to flow through a manifold-channel structure.

In order to apply the embedded cooling commercially, it is very important to develop a self-cooling type semiconductor package in which a packaging unit including a manifold and a cooling device is formed and a semiconductor with a micro channel is attached to the rear of the packaging unit. In developing the self-cooling type semiconductor package, the following technical difficulties arise.

That is, according to a package unit manufactured using a manufacturing method according to the prior art, first, the size of a manifold wall included in a package is so small that mechanical processing is difficult, and second, the cooling effect is reduced due to a gap between the rear of a semiconductor and the package, and lastly, a process of attaching the semiconductor to the package is complicated, which increases the process cost.

### DISCLOSURE

### Technical Problem

The present disclosure is directed to providing a direct cooling type semiconductor package unit capable of forming a structure in which a substrate and a heat sink unit are in close contact with each other by using a thin film type structure that is moldable to have pattern structures of various shapes through a lithography process, so that a cooling fluid may flow into a flow channel side of the substrate without loss, thereby improving cooling performance of a semiconductor device.

### Technical Solution

In one aspect of the present disclosure, there is provided a direct cooling type semiconductor package unit including a substrate made of a material capable of manufacturing a semiconductor device, and having a material layer for forming the semiconductor device stacked on one side of the substrate, and a flow channel through which a cooling fluid flows formed on the other side of the substrate to enable direct cooling of the semiconductor device using the cooling fluid; a packaging block disposed at a position spaced apart from the substrate for packaging the semiconductor device, and having an electrode electrically connected to the semiconductor device through wiring and placed thereon to be insulated; a heat sink unit disposed on a lower side of the packaging block and having a fluid movement region formed at a position corresponding to a flow channel of the substrate; and a thin film type structure disposed between the substrate and the heat sink unit for coupling between the substrate and the heat sink unit and being moldable to have pattern structures of various shapes through a lithography process.

The heat sink unit may include a flow path forming portion in which the fluid movement region is formed, and, in the flow path forming portion, an inflow line until the cooling fluid flows into the flow channel of the substrate and a discharge line until the cooling fluid is discharged after flowing into the flow channel are formed to be partitioned from each other, so that the cooling fluid flowing into the inflow line is configured to pass through the flow channel of the substrate without being directly discharged to the discharge line, and the fluid movement region located in a region corresponding to the flow channel among the inflow line and the discharge line includes an inflow region and a discharge region that are partitioned from each other with a partition portion therebetween.

The thin film type structure may include an edge portion disposed between the substrate and the heat sink unit in the form that surrounds the fluid movement region of the heat sink unit; and a pattern portion formed at a position where the edge portion is divided into two and stacked in a partition portion of the fluid movement region to have the same height as the edge portion so as to be in close contact with the flow channel of the substrate.

The pattern portion may have a pattern structure in a zigzag shape.

In another aspect of the present disclosure, there is provided a method of manufacturing a direct cooling type semiconductor package unit including a device and substrate preparation step of stacking a material layer for forming a semiconductor device on one side of a substrate made of a material including silicon, forming the semiconductor device by performing a semiconductor process on the material layer, and forming a flow channel through which a cooling fluid flows on the other side of the substrate to enable direct cooling of the semiconductor device using the cooling fluid; a heat sink unit preparation step of disposing a heat sink unit on a lower side of the substrate, the heat sink unit including a flow path forming portion in which a fluid movement region communicating with the flow channel of the substrate is formed; a wiring step of disposing a packaging block surrounding the substrate on the heat sink unit for packaging the semiconductor device and electrically connecting an electrode placed on the packaging block to the semiconductor device; a laminating step of coupling a thin film type structure that is moldable to have pattern structures of various shapes through a lithography process to an upper surface of the heat sink unit; a pattern forming step of forming a pattern structure that allows the fluid movement region of the heat sink unit and the flow channel of the substrate to communicate with each other by performing an exposure and development process on the thin film type structure; and a coupling step of coupling the substrate to the heat sink unit by using the thin film type structure.

The heat sink unit preparation step may include a flow path forming body preparation step of forming a flow path forming portion in which an inflow line until the cooling fluid flows into the flow channel of the substrate and a discharge line until the cooling fluid is discharged after flowing into the flow channel are partitioned from each other (the fluid movement region is included in the inflow line and the discharge line); a cover member preparation step of forming a cooling fluid inflow hole, a discharge hole, and a fluid movement hole corresponding to the fluid movement region in a cover member the shape of a plate; and a coupling step of coupling a flow path forming body to the cover member.

The pattern forming step may include forming an edge portion coupled to surround the fluid movement region of the heat sink unit, and a pattern portion at a position where the edge portion is divided into two so as to be in close contact with the flow channel of the substrate by performing the exposure and development process on the thin film type structure.

### Advantageous Effects

The direct cooling type device for the integrated circuit according to the present disclosure having the above-described configuration includes a thin film type structure manufactured through a lithography process using a dry film resist (DFR) film, wherein the thin film type structure includes the edge portion for coupling between the substrate and the heat sink unit, and the pattern portion for guiding the cooling fluid to the flow channel of the substrate without loss at the position dividing the edge portion into two and corresponding to the partition portion of the heat sink unit, thereby enabling simplification of the structure and slimming of the product, and deriving the effect of maximizing the cooling efficiency of the semiconductor device.

### DESCRIPTION OF DRAWINGS

FIG. 1 is a perspective view of a direct cooling type semiconductor package unit according to an embodiment of the present disclosure.

FIG. 2 is an exploded perspective view of an embodiment of the present disclosure.

FIG. 3 is a bottom exploded perspective view of an embodiment of the present disclosure.

FIG. 4 is a perspective view of a thin film type structure employed in an embodiment of the present disclosure.

FIG. 5 is a plan view of an embodiment of the present disclosure.

FIG. 6 is a diagram for explaining a cooling fluid flow path of an embodiment of the present disclosure.

FIG. 7 is a cross-sectional view of an embodiment of the present disclosure.

FIGS. 8 to 11 are diagrams for explaining a manufacturing process of an embodiment of the present disclosure.

### BEST MODE

In order to clarify the understanding of the present disclosure in the following description, descriptions of well-known technology of the features of the present disclosure will be omitted. The following embodiments are detailed descriptions to help the understanding of the present disclosure, and do not to limit the scope of the present disclosure. Accordingly, equivalent inventions performing the same functions as those of the present disclosure will also fall within the scope of the present disclosure.

In addition, in the following description, the same reference numeral mean the same configuration, and unnecessary redundant descriptions and descriptions of well-known technologies will be omitted. In addition, the description of each embodiment of the present disclosure that overlaps with the description of the technology that is the background of the invention will also be omitted.

Hereinafter, a direct cooling type semiconductor package unit according to an embodiment of the present disclosure will be described in detail with reference to the accompanying drawings.

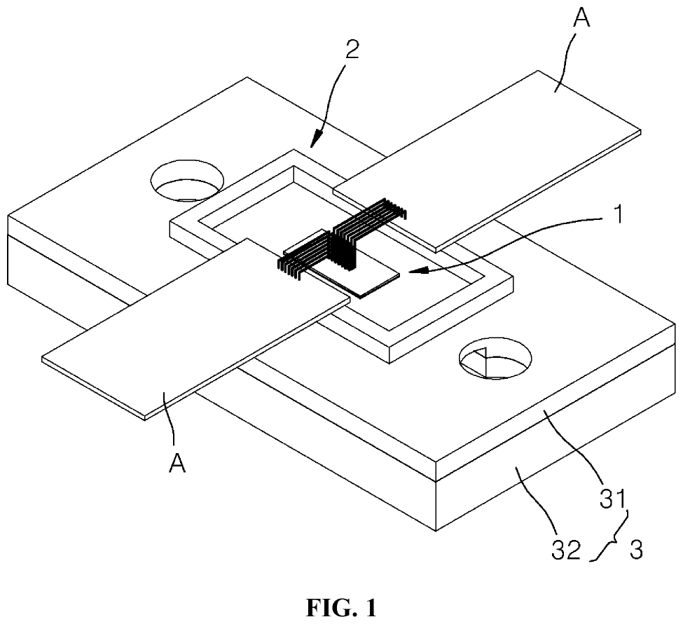

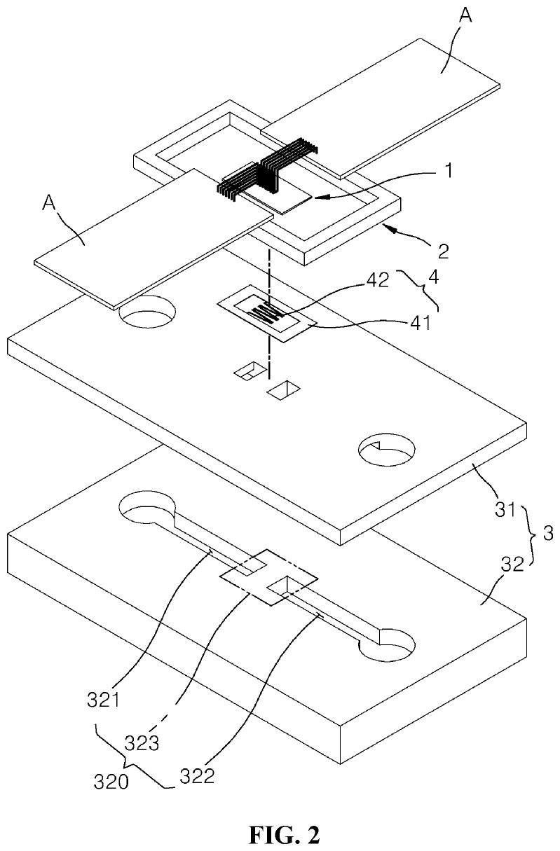

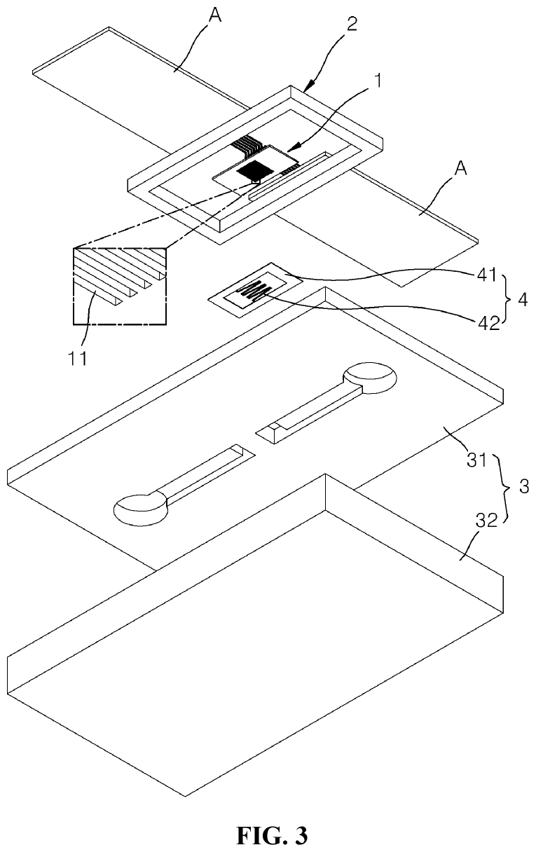

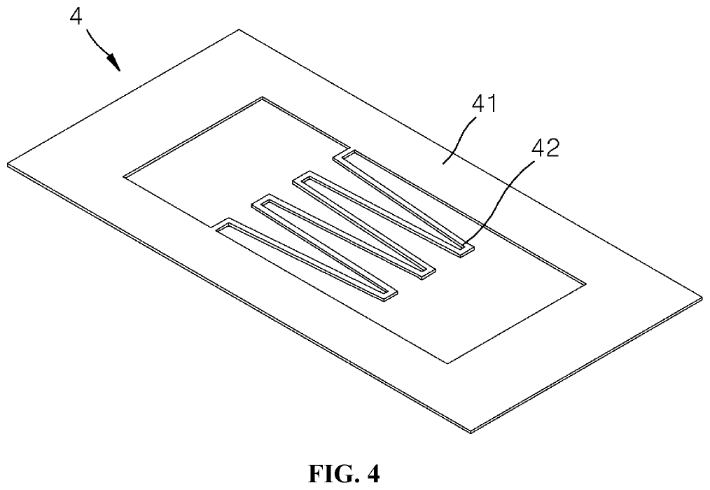

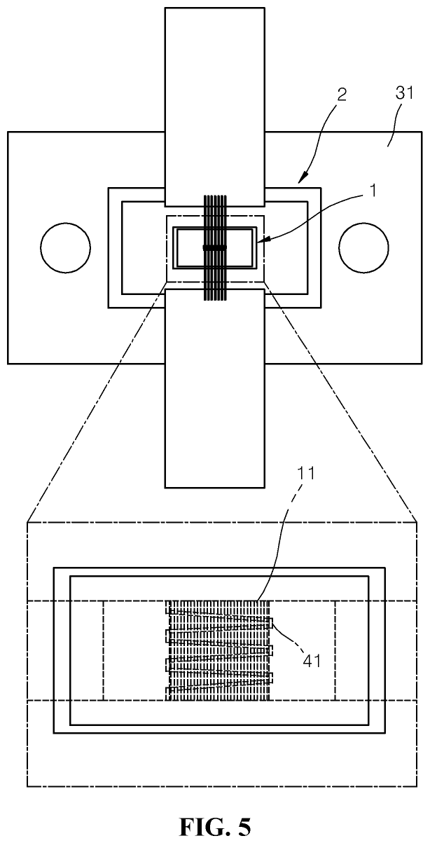

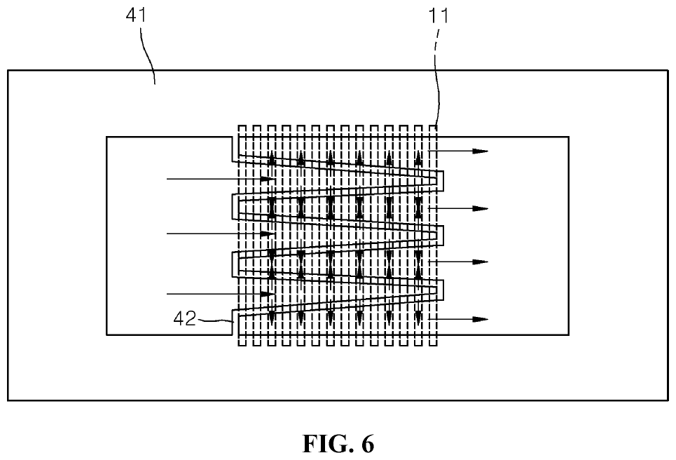

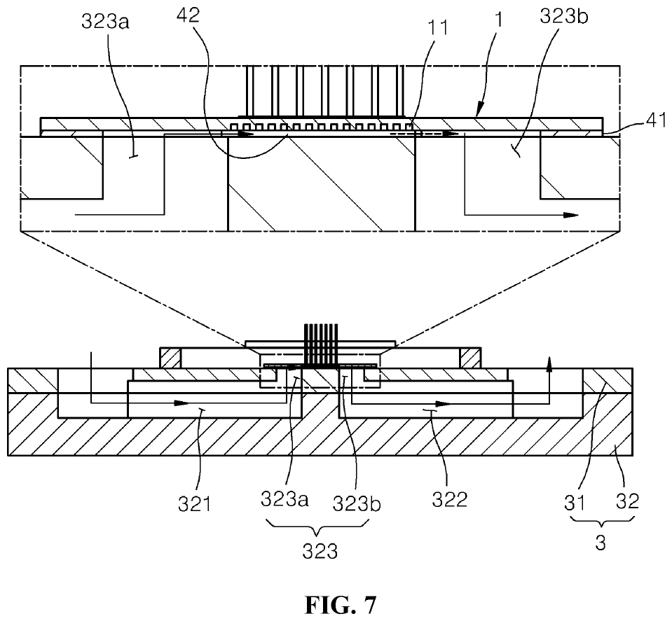

FIG. 1 is a perspective view of a direct cooling type semiconductor package unit according to an embodiment of the present disclosure. FIG. 2 is an exploded perspective view of an embodiment of the present disclosure. FIG. 3 is a bottom exploded perspective view of an embodiment of the present disclosure. FIG. 4 is a perspective view of a thin film type structure employed in an embodiment of the present disclosure. FIG. 5 is a plan view of an embodiment of the present disclosure. FIG. 6 is a diagram for explaining a cooling fluid flow path of an embodiment of the present disclosure. FIG. 7 is a cross-sectional view of an embodiment of the present disclosure.

As shown in FIGS. 1 to 4, the direct cooling type semiconductor package unit according to an embodiment of the present disclosure allows a cooling fluid to flow directly to the substrate 1 on which a semiconductor device is formed, thereby improving the cooling efficiency of the semiconductor device, and includes the substrate 1, a packaging block 2, a heat sink unit 3, and a thin film type structure 4.

The substrate 1 corresponds to a wafer for manufacturing the semiconductor device, is made of a material capable of manufacturing the semiconductor device, such as Si or SiC, has a material layer for forming the semiconductor device stacked on one side of the substrate 1, and, as well shown in an enlarged portion of FIG. 3, a flow channel 11 providing a movement path of the cooling fluid formed on the other side of the substrate 1, enabling direct cooling of the semiconductor device by the cooling fluid.

The substrate 1 employed in the present embodiment is configured to be integrally formed of a single material including silicon, but the present disclosure is not limited thereto, and, for example, may also be configured in a structure in which a base layer for forming the semiconductor device and a channel layer for forming the flow channel 11 of the cooling fluid are separately manufactured and then coupled to each other.

The packaging block 2 is disposed at a position spaced apart from the substrate 1 for packaging the semiconductor device, and has an electrode, is made of an insulating material such as ceramic, and has an electrode A electrically connected to the semiconductor device through wiring placed thereon.

As well shown in FIGS. 2 and 7, the heat sink unit 3 on a lower side of the packaging block 2 and has a fluid movement region 323 disposed at a position corresponding to flow channel 11 of the substrate 1 so as to communicate with the flow channel 11. Here, the fluid movement region 323 refers to a region including an inflow region 323a and a discharge region 323b of the cooling fluid. That is, the present embodiment is configured so that the cooling fluid may sequentially pass through the inflow region 323a, the flow channel 11 of the substrate 1, and the discharge region 323b, thereby enabling direct cooling of the substrate 1 by the cooling fluid.

The heat sink unit 3 may be formed of a single material, but in the present embodiment, includes a flow path forming body 32 with a flow path forming portion 320 formed so as to smoothly form the flow path forming portion 320 and a cover member 31 coupled to the flow path forming body 32.

The thin film type structure 4 is disposed between the substrate 1 and the heat sink unit 3 for coupling between the substrate 1 and the heat sink unit 3, and is moldable to have pattern structures of various shapes through a dry film resist (DFR) lithography process, such as a DFR structure.

According to the prior art, a substrate and a heat sink unit may be coupled to each other through eutectic bonding using an Au—Sn eutectic alloy, but according to this method, there is a disadvantage in that a cooling which flows into an inlet region of the heat sink unit does not sufficiently pass through a flow channel of the substrate and flows out to a discharge region due to the thickness of an alloy, which ultimately deteriorates the cooling performance of the semiconductor device. In order to overcome this disadvantage, a method in which a partition portion having the thickness corresponding to the alloy partitions the inlet region and the outlet region to minimize the outflow of the cooling fluid may be proposed. In the case of Au—Sn eutectic alloy, there is a problem in that pattern structures of various shapes is not smooth.

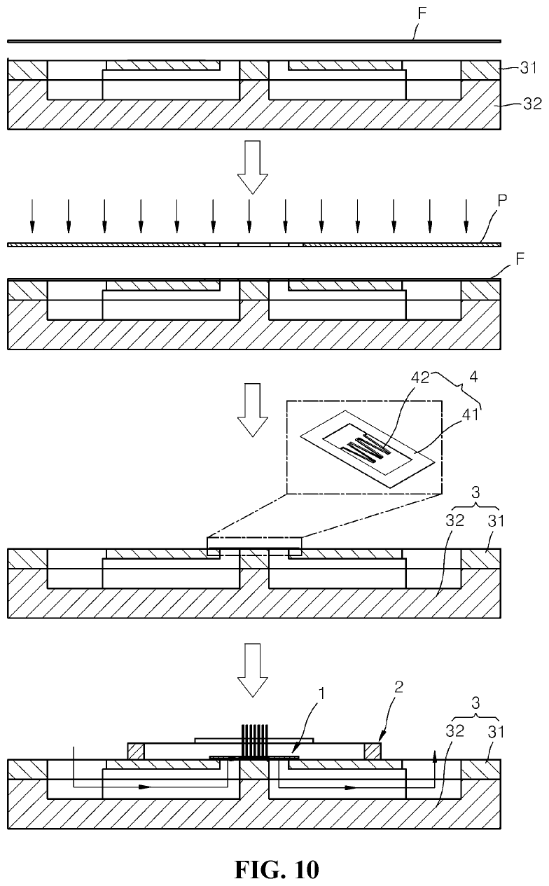

However, according to the present disclosure, it is possible to form a structure with patterns of various shapes by performing a lithography process including exposure and development processes using a photomask P on a DFR film F (see FIG. 10), and thus, there is an advantage in that it is easy to design a structure that allows as much cooling fluid as possible to pass through the flow channel 11 of the substrate 1 by, for example, manufacturing the partition portion in a zigzag shape.

The packaging unit for direct cooling of the semiconductor device according to an embodiment of the present disclosure having the configuration above may be configured so that the flow channel 11 through which the cooling fluid may flow in the substrate 1 for forming the semiconductor device is formed, the heat sink unit 3 having the fluid movement region 323 communicating with the flow channel 11 of the substrate on the packaging block 2 disposed to surround the semiconductor device for packaging the semiconductor device is provided, and the substrate 1 and the heat sink unit 3 are coupled to each other using the DFR film F that is formed into pattern structures of various shapes through the lithography process, and thus, as shown in FIG. 6, a relatively large amount of cooling fluid may directly pass through the flow channel 11 of the substrate 1 for an appropriate time, resulting in the advantage of improving the thermal management efficiency of the semiconductor device and the performance and lifespan of the product.

In addition, the packaging unit for direct cooling of the semiconductor device according to an embodiment of the present disclosure may also form a flow path structure for implementing direct cooling of the semiconductor device by using a configuration used for packaging of the semiconductor device as the heat sink unit 3 is configured to be provided on the packaging block 2, resulting in the advantage of achieving simplification of the structure and slimming of the product along with the improvement of the thermal management efficiency of semiconductor device.

The heat sink unit 3 employed in the present embodiment includes the flow path forming portion 320 in which the fluid movement region 323 is formed, and the flow path forming portion 320 includes various structures or pattern shapes communicating with the flow channel 11 of the substrate 1, but as well shown in FIGS. 2 and 4, an inflow line 321 until the cooling fluid flows into the flow channel 11 of the substrate 1 and a discharge line 322 until the cooling fluid is discharged after flowing into the flow channel 11 are formed to be partitioned from each other in the flow path forming portion 320, so that a discharge path of the heated fluid by passing through the flow channel 11 and an inflow path of a new fluid in a low temperature state into the flow channel 11 are distinguished, and thus, the improved cooling efficiency may be expected.

The fluid movement region 323 located in a region corresponding to the flow channel 11 among the inflow line 321 and the discharge line 322 may include the inflow region 323a and the discharge region 323b that are partitioned from each other with a partition portion therebetween.

The thin film type structure 4 employed in the present embodiment includes an edge portion 41 and a pattern portion 42, as well shown in FIGS. 4 and 5. The edge portion 41 is a portion disposed between the substrate 1 and the heat sink unit 3 in the form that surrounds the fluid movement region 323 of the heat sink unit 3, and the pattern portion 42 is formed at a position where the edge portion 41 is divided into two and stacked in the partition portion of the fluid movement region 323 to have the same height as the edge portion 41 so as to be in close contact with the flow channel 11 of the substrate 1 without a gap.

The present embodiment having such a configuration includes the thin film type structure 4 manufactured through the lithography process, and the thin film type structure 4 is configured to include the edge portion 41 for coupling between the substrate 1 and the heat sink unit 3 and the pattern portion 42 for guiding the cooling fluid to the flow channel 11 of the substrate 1 without loss at a position dividing the edge portion 41 into two and corresponding to the partition portion of the heat sink unit 3, which has the advantage of enabling simplification of the structure and slimming of the product and maximizing the cooling efficiency of the semiconductor device.

The pattern portion 42 may have a zigzag pattern structure so that as much cooling fluid as possible may pass through the flow channel 11 of the substrate 1 for an appropriate time, as shown in FIG. 6.

Meanwhile, the thin film type structure 4 employed in the present embodiment may include a polymer synthetic resin material constituting the DFR film F and at least one material among graphene, carbon nanotubes, gold nanoparticles, and silver nanoparticles for increasing thermal conductivity so as to simultaneously satisfy formability and thermal conductivity.

Hereinafter, a method of manufacturing a direct cooling type semiconductor package unit according to an embodiment of the present disclosure will be described.

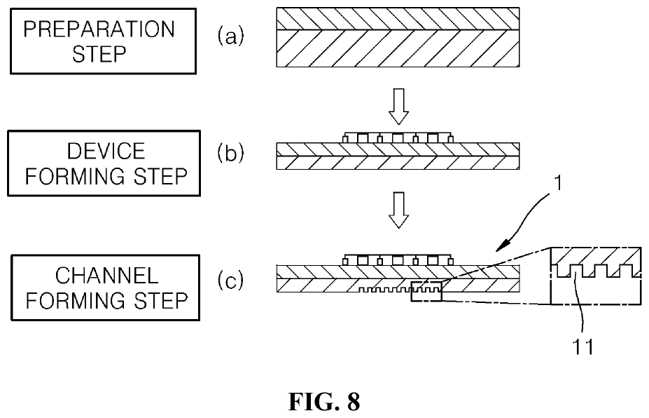

FIGS. 8 to 11 are diagrams for explaining a manufacturing process of an embodiment of the present disclosure.

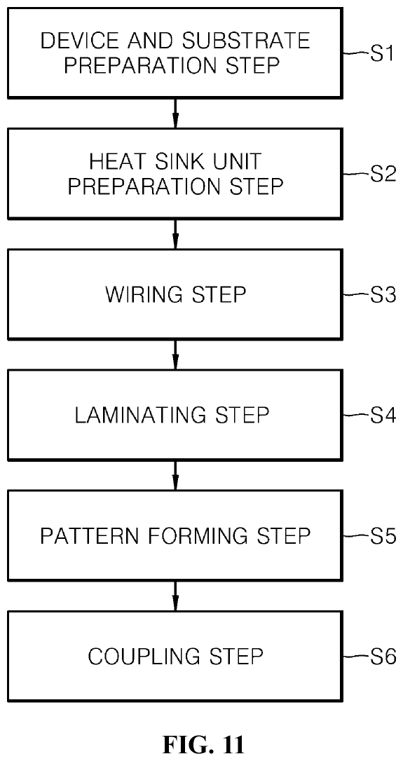

As shown in FIG. 11, the method of manufacturing the direct cooling type semiconductor package unit according to an embodiment of the present disclosure includes a device and substrate preparation step (S1), a heat sink unit preparation step (S2), a wiring step (S3), a laminating step (S4), a pattern forming step (S5), and a coupling step (S6).

As shown in FIG. 8, in the device and substrate preparation step (S1), a process of stacking a material layer for forming a semiconductor device on one side of the substrate 1 made of a material capable of manufacturing the semiconductor device, such as silicon, performing a semiconductor process on the material layer, forming the semiconductor device, and forming the flow channel 11 through which a cooling fluid flows on the other side of the substrate 1 to enable direct cooling of the semiconductor device using the cooling fluid.

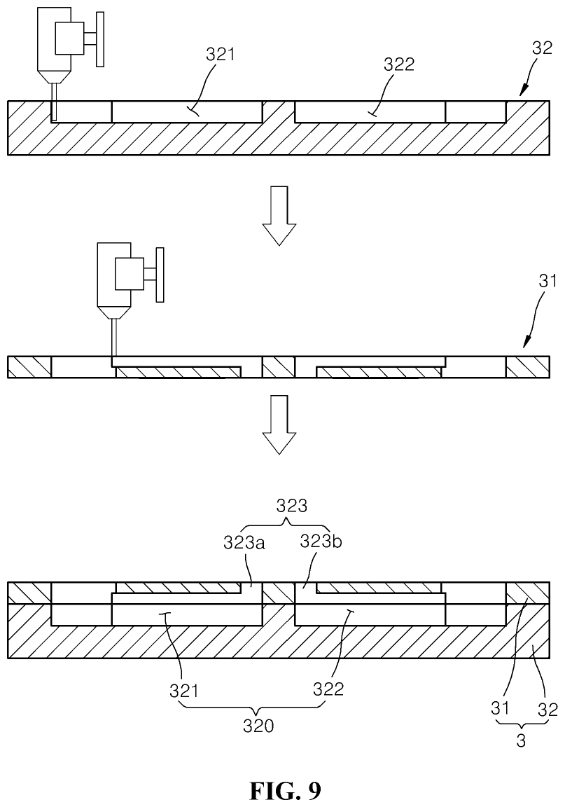

As shown in FIG. 9, in the heat sink unit preparation step (S2), a process of disposing the heat sink unit 3 in which the fluid movement region 323 providing a movement path of the cooling fluid is formed on a lower side of the substrate 1 is performed. Here, the fluid movement region 323 may communicate with the flow channel 11 of the substrate 1 to allow the cooling fluid to flow into the flow channel 11.

In the wiring step (S3), a process of disposing the packaging block 22 surrounding the substrate 1 in the heat sink unit 3 for packaging the semiconductor device, and electrically connecting the electrode A placed on the packaging block 2 to the semiconductor device is performed.

As shown in FIG. 10, in the laminating step (S4), a process of coupling the DFR film F capable of performing a lithography process to an upper surface of the heat sink unit 3 is performed. Here, the DFR film F has the advantage of being moldable to have pattern structures of various shapes.

In the pattern forming step (S5), a process of forming the thin film type structure 4 that allows the fluid movement region 323 of the heat sink unit 3 and the flow channel 11 of the substrate 1 to communicate with each other by performing an exposure and development process on the DFR film F using the photomask P.

That is, when the fluid movement region 323 includes the inflow region 323a for allowing the cooling fluid with the low temperature to flow to the flow channel 11 of the substrate 1 and the discharge region 323b for discharging the cooling fluid with increased temperature by passing through a cooling channel, in the pattern forming step (S5), a process of forming the DFR film F disposed between the substrate 1 and the heat sink unit 3 as the thin film type structure 4 having a pattern structure that prevents interference with the inflow region 323a and the discharge region 323b.

The pattern forming step (S5) may include forming, in the thin film type structure 4, the edge portion 41 coupled to surround the fluid movement region 323 of the heat sink unit 3, and the pattern portion 42 at a position dividing the edge portion 41 into two and partitioning the inflow region 323a and the discharge region 323b so as to be in close contact with the flow channel 11 of the substrate 1 by performing a semiconductor process.

In the coupling step (S6), a process of coupling the substrate 1 to the heat sink unit 3 by applying heat to the thin film type structure 4 in which the pattern structure described above is formed is performed.

The method of manufacturing the direct cooling type semiconductor package unit according to an embodiment of the present disclosure having the configuration described above includes the pattern forming step (S5) of forming a pattern on the thin film type structure 4 manufactured through the lithography process and the coupling step (S6) of coupling the substrate 1 to the heat sink unit 3 by using the thin film type structure 4 on which the pattern is formed, which allows the cooling fluid to flow into the flow channel 11 of the substrate 1 without loss, resulting in the advantages of improving the thermal efficiency of semiconductor device and easily and precisely manufacturing the package unit from which the improved thermal efficiency may be expected.

The heat sink unit preparation step (S2) employed in the present embodiment includes a flow path forming body preparation step, a cover member preparation step, and a coupling step as well shown in FIG. 9 to easily form a path through which the cooling fluid may flow.

In the flow path forming body preparation step, a process of forming the flow path forming portion 320 is performed. In the flow path forming portion 320, the inflow line 321 until the cooling fluid flows into the flow channel 11 of the substrate 1 and the discharge line 322 until the cooling fluid is discharged after flowing into the flow channel 11 are partitioned from each other, and the fluid movement region 323 is included in the inflow line 321 and the discharge line 322.

Here, the flow path forming body 32 may be manufactured by various methods such as 3D metal printing method as well as CNC process using a metal plate.

In the cover member preparation step, the cover member 31 in which a cooling fluid inflow hole, a discharge hole, and a fluid movement hole corresponding to the fluid movement region 323 are formed in the cover member 31 the shape of a plate is prepared.

In the coupling step, a process of coupling the flow path forming body 32 to the cover member 31 is performed.

In the present embodiment having such configuration, the step of preparing the heat sink unit 3 is divided into the flow path forming body preparation step and the cover member preparation step, so that the flow path structure of the heat sink unit 3 may be more easily formed, which has the advantage of increasing the mass production of the product.

Although various embodiments of the present disclosure have been described above, the present embodiment and the drawings attached to the present specification merely clearly present a part of the technical idea included in the present disclosure, and it will be obvious that all modifications and specific embodiments that may be easily inferred by those skilled in the art within the scope of the technical idea included in the specification and drawings of the present disclosure are included in the scope of the present disclosure.

[EXPLANATION OF REFERENCE NUMERALS]

| | |
|---|---|
| 1: Substrate | 11: Flow channel |
| 2: Packaging block | 3: Heat sink unit |
| 31: Cover member | 32: Flow path forming body |
| 320: Flow path forming portion | 321: Inflow line |
| 322: Discharge line | 323: Fluid movement region |
| 323a: Inflow region | 323b: Discharge region |
| 4: Thin film type structure | 41: Edge portion |
| 42: Pattern portion | A: Electrode |
| F: DFR film | P: Photomask |

What is claimed is:

1. A direct cooling type semiconductor package unit comprising:
a substrate made of a material capable of manufacturing a semiconductor device, and having a material layer for forming the semiconductor device stacked on one side of the substrate, and a flow channel through which a cooling fluid flows formed on the other side of the substrate to enable direct cooling of the semiconductor device using the cooling fluid;
a packaging block disposed at a position spaced apart from the substrate for packaging the semiconductor device, and having an electrode electrically connected to the semiconductor device through wiring and placed thereon to be insulated;
a heat sink unit disposed on a lower side of the packaging block and having a fluid movement region formed at a position corresponding to the flow channel of the substrate; and
a thin film type structure disposed between the substrate and the heat sink unit for coupling between the substrate and the heat sink unit and being moldable to have pattern structures of various shapes through a lithography process.

2. The direct cooling type semiconductor package unit of claim 1, wherein the heat sink unit includes a flow path forming portion in which the fluid movement region is formed, and
in the flow path forming portion, an inflow line until the cooling fluid flows into the flow channel of the substrate and a discharge line until the cooling fluid is discharged after flowing into the flow channel are formed to be partitioned from each other, so that the cooling fluid flowing into the inflow line is configured to pass through the flow channel of the substrate without being directly discharged to the discharge line, and the fluid movement region located in a region corresponding to the flow channel among the inflow line and the discharge line includes an inflow region and a discharge region that are partitioned from each other with a partition portion therebetween.

3. The direct cooling type semiconductor package unit of claim 2, wherein the thin film type structure includes
an edge portion disposed between the substrate and the heat sink unit in the form that surrounds the fluid movement region of the heat sink unit; and
a pattern portion formed at a position where the edge portion is divided into two and stacked in a partition portion of the fluid movement region to have a same height as the edge portion so as to be in close contact with the flow channel of the substrate.

4. The direct cooling type semiconductor package unit of claim 1, wherein the pattern portion has a pattern structure in a zigzag shape.

5. The direct cooling type semiconductor package unit of claim 1, wherein
the thin film type structure includes a polymer synthetic resin material constituting a DFR (dry film resist) film, and at least one material among graphene, carbon nanotubes, gold nanoparticles, and silver nanoparticles for increasing thermal conductivity.

6. A method of manufacturing a direct cooling type semiconductor package unit, the method comprising:
a device and substrate preparation step of stacking a material layer for forming a semiconductor device on one side of a substrate made of a material comprising silicon, forming the semiconductor device by performing a semiconductor process on the material layer, and forming a flow channel through which a cooling fluid flows on the other side of the substrate to enable direct cooling of the semiconductor device using the cooling fluid;
a heat sink unit preparation step of disposing a heat sink unit on a lower side of the substrate, the heat sink unit comprising a flow path forming portion in which a fluid movement region communicating with the flow channel of the substrate is formed;
a wiring step of disposing a packaging block surrounding the substrate on the heat sink unit for packaging the semiconductor device and electrically connecting an electrode placed on the packaging block to the semiconductor device;
a laminating step of coupling a thin film type structure that is moldable to have pattern structures of various shapes through a lithography process to an upper surface of the heat sink unit;
a pattern forming step of forming a pattern structure that allows the fluid movement region of the heat sink unit and the flow channel of the substrate to communicate with each other by performing an exposure and development process on the thin film type structure; and
a coupling step of coupling the substrate to the heat sink unit by using the thin film type structure.

7. The method of claim 6, wherein the heat sink unit preparation step comprises:
a flow path forming body preparation step of forming a flow path forming portion in which an inflow line until the cooling fluid flows into the flow channel of the substrate and a discharge line until the cooling fluid is discharged after flowing into the flow channel are partitioned from each other (the fluid movement region is included in the inflow line and the discharge line);
a cover member preparation step of forming a cooling fluid inflow hole, a discharge hole, and a fluid movement hole corresponding to the fluid movement region in a cover member the shape of a plate; and
a coupling step of coupling a flow path forming body to the cover member.

8. The method of claim 6, wherein the pattern forming step comprises forming an edge portion coupled to surround the fluid movement region of the heat sink unit, and a pattern portion at a position where the edge portion is divided into two so as to be in close contact with the flow channel of the substrate by performing the exposure and development process on the thin film type structure.
